(19) United States
(12) Patent Application Publication
(10) Pub. No.: US 2018/0219113 A1
(43) Pub. Date: Aug. 2, 2018

(54) CIGS BASED PHOTOVOLTAIC CELL WITH NON-STOICHIOMETRIC METAL SULFIDE LAYER AND METHOD AND APPARATUS FOR MAKING THEREOF

(71) Applicant: BEIJING APOLLO DING RONG SOLAR TECHNOLOGY CO., LTD., Beijing (CN)

(72) Inventors: Rouin FARSHCHI, Palo Alto, CA (US); Geordie ZAPALAC, Santa Clara, CA (US); Timothy NAGLE, Campbell, CA (US)

(21) Appl. No.: 15/419,518

(22) Filed: Jan. 30, 2017

(51) Int. Cl. H01L 31/0392; H01L 31/0224; H01L 31/18; C23C 14/34

(52) U.S. Cl. CPC H01L 31/03923; C23C 14/34; H01L 31/18; H01L 31/022425

(57) ABSTRACT

A method of making a photovoltaic device includes forming a p-type compound semiconductor material layer comprising copper, indium, gallium and a chalcogen over a substrate, and forming an n-type metal sulfide layer on the p-type compound semiconductor material layer by sputtering process employing at least one metal and sulfur containing sputtering target having a non-stoichiometric composition in which a metal-to-sulfur atomic ratio is greater than 1.

### BACKGROUND

The present disclosure is directed generally to an apparatus and method for manufacturing a semiconductor device, and specifically to a photovoltaic cell having a highly conductive n-type semiconductor material layer and an apparatus and method for manufacturing the photovoltaic cell.

A “thin-film” photovoltaic material refers to a polycrystalline or amorphous photovoltaic material that is deposited as a layer over a substrate that provides structural support. The thin-film photovoltaic materials are distinguished from single crystalline semiconductor materials that have a higher manufacturing cost. Some of the thin-film photovoltaic materials that provide high conversion efficiency include chalcogen-containing compound semiconductor material, such as copper indium gallium selenide (CIGS).

Thin-film photovoltaic cells (also known as solar cells) may be manufactured using a roll-to-roll coating system based on sputtering, evaporation, or chemical vapor deposition (CVD) techniques. A thin foil substrate, such as a foil web substrate, is fed from a roll in a linear belt-like fashion through the series of individual vacuum chambers or a single divided vacuum chamber where it receives the required layers to form the thin-film photovoltaic cells. In such a system, a foil having a finite length may be supplied on a roll. The end of a new roll may be coupled to the end of a previous roll to provide a continuously fed foil layer.

Conductivity of semiconductor material layers in a photovoltaic cell affect performance of the photovoltaic cell by affecting the characteristics of the recombination zone around a p-n junction or a p-i-n junction. In photovoltaic cells employing a combination of a copper-indium-gallium-chalcogenide p-type layer and a metal sulfide n-type layer, high resistivity of the metal sulfide n-type layer can adversely impact performance metrics of the photovoltaic cells, such as efficiency, open circuit voltage, closed circuit current density, and fill factor.

### SUMMARY

One embodiment provides a method of making a photovoltaic device which forming a p-type compound semiconductor material layer comprising copper, indium, gallium and a chalcogen over a substrate, and forming an n-type metal sulfide layer on the p-type compound semiconductor material layer by sputtering process employing at least one metal and sulfur containing sputtering target having a non-stoichiometric composition in which a metal-to-sulfur atomic ratio is greater than 1.

According to another aspect of the present disclosure, a semiconductor device manufacturing apparatus is provided, which comprises: a first process module configured to receive a substrate through a first entrance and to extract the substrate through a first exit and including at least one first sputtering target comprising copper, indium, and gallium and a chalcogen source and configured for deposition of a p-type compound semiconductor material layer comprising copper, indium, gallium, and a chalcogen on the substrate during transit therethrough, and a second process module configured to receive the substrate from the first process module through a second entrance and to extract the substrate through a second exit and including at least one second sputtering target configured for deposition of an n-type metal sulfide layer on the substrate during transit of the substrate through the second process module, wherein one of the at least one second sputtering target comprises a second sputtering target having a non-stoichiometric composition in which a metal-to-sulfur atomic ratio is in a range from 1.05 to 1.20.

Another embodiment provides a method of making a semiconductor device, comprising forming a p-type compound semiconductor material layer comprising copper, indium, gallium, and a chalcogen over a substrate in a first process module by a first sputtering process employing at least one first sputtering target comprising copper, indium, and gallium, forming an n-type metal sulfide layer on the p-type compound semiconductor material layer in a second process module by a second sputtering process employing at least one second sputtering target, and forming a conductive metal sulfide-oxide compound layer on the n-type metal sulfide layer in a third process module by a third sputtering process employing a third sputtering target in an oxidizing ambient.

Another embodiment provides a photovoltaic cell, comprising a first electrode located over a substrate, a p-type compound semiconductor material layer located over the first electrode layer and comprising copper, indium, gallium and a chalcogen, a polycrystalline metal rich metal sulfide n-type compound semiconductor material layer located over the p-type compound semiconductor material layer, and a second electrode located over the metal rich metal sulfide n-type compound semiconductor material layer.

Another embodiment provides a photovoltaic cell, comprising a first electrode located over a substrate, a p-type compound semiconductor material layer located over the first electrode layer and comprising copper, indium, gallium and a chalcogen, a metal sulfide n-type compound semiconductor material layer located over the p-type compound semiconductor material layer, a conductive metal sulfide-oxide compound layer located over the metal sulfide n-type compound semiconductor material layer, and a second electrode located over the conductive metal sulfide-oxide compound layer.

### BRIEF DESCRIPTION OF THE DRAWINGS

FIG. 1 is a schematic vertical cross sectional view of a thin-film photovoltaic cell the can be manufactured according to a first embodiment of the present disclosure.

FIG. 2 is a schematic diagram of a first exemplary modular deposition apparatus that can be used to manufacture the photovoltaic cell illustrated in FIG. 1 according to an embodiment of the present disclosure.

FIG. 3 is a schematic vertical cross-sectional view of a first alternate configuration of the thin-film photovoltaic cell according to a second embodiment of the present disclosure.

FIG. 4 is a schematic diagram of a second exemplary modular deposition apparatus that can be used to manufacture the photovoltaic cell illustrated in FIG. 5 according to an embodiment of the present disclosure.

FIG. 5 is a schematic vertical cross-sectional view of a second alternate configuration of the thin-film photovoltaic cell according to a third embodiment of the present disclosure.

### DETAILED DESCRIPTION

As discussed above, the present disclosure is directed to an apparatus and method for manufacturing a photovoltaic cell having a highly conductive n-type semiconductor material layer, the various aspects of which are described herein.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed to refer to a same element across the specification and the claims of the instant disclosure. Same reference numerals to the same element or similar elements. Elements with the same reference numerals are presumed to have the same composition unless described otherwise.

As used herein, a first element located “on” a second element can be located on the exterior side of a surface of the second element or on the interior side of the second element. As used herein, a first element is located “directly on” a second element if there exist a direct physical contact between a surface of the first element and a surface of the second element. As used herein, an element is “configured” to perform a function if the structural components of the element are inherently capable of performing the function due to the physical and/or electrical characteristics thereof.

Embodiments of the present disclosure provide a method of reducing electrical resistivity of n-type compound semiconductor layer in a photovoltaic cell for enhanced performance.

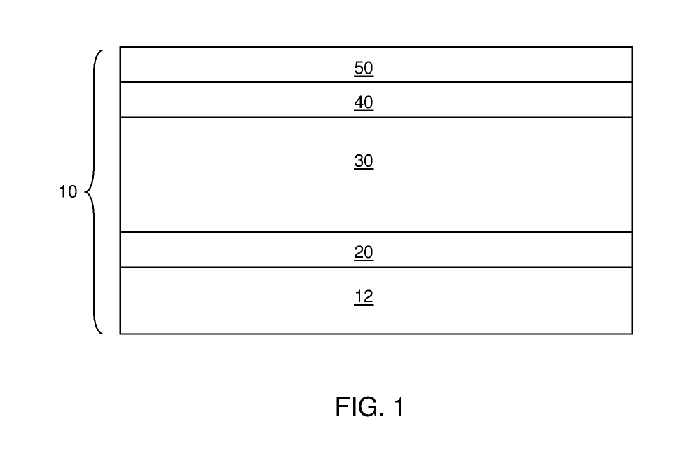

Referring to FIG. 1, a vertical cross-sectional view of a photovoltaic cell 10 is illustrated. The photovoltaic cell 10 includes a substrate, such as an electrically conductive substrate 12, a first electrode 20, a p-type compound semiconductor material layer 30, an n-type compound semiconductor material layer 40, a second electrode 50, and an optional antireflective (AR) coating layer (not shown).

The substrate 12 is preferably a flexible, electrically conductive material, such as a metallic foil that is fed into a system of one or more process modules as a web for deposition of additional layers thereupon. For example, the metallic foil of the conductive substrate 12 can be a sheet of a metal or a metallic alloy such as stainless steel, aluminum, or titanium. If the substrate 12 is electrically conductive, then it may comprise a part of the back side (i.e., first) electrode of the cell 10. Thus, the first (back side) electrode of the cell 10 may be designated as (20, 12). Alternatively, the conductive substrate 12 may be an electrically conductive or insulating polymer foil. Still alternatively, the substrate 12 may be a stack of a polymer foil and a metallic foil. In another embodiment, the substrate 12 may be a rigid glass substrate or a flexible glass substrate. The thickness of the substrate 12 can be in a range from 100 microns to 2 mm, although lesser and greater thicknesses can also be employed.

The first or back side electrode 20 may comprise any suitable electrically conductive layer or stack of layers. For example, electrode 20 may include a metal layer, which may be, for example, molybdenum. Alternatively, a stack of molybdenum and sodium and/or oxygen doped molybdenum layers may be used instead, as described in U.S. Pat. No. 8,134,069, which is incorporated herein by reference in its entirety. In another embodiment, the first electrode 20 can include a molybdenum material layer doped with K and/or Na, i.e., MoKₓ or Mo(Na,K)ₓ, in which x can be in a range from 1.0×10⁻⁶ to 1.0×10⁻². The electrode 20 can have a thickness in a range from 500 nm to 1 micron, although lesser and greater thicknesses can also be employed.

The p-type compound semiconductor material layer 30 can include a p-type copper indium gallium selenide (CIGS), which functions as a semiconductor absorber layer. The thickness of the p-type compound semiconductor material layer 30 can be in a range from 1 microns to 5 microns, although lesser and greater thicknesses can also be employed. The CIGS p-type compound semiconductor material layer 30 can also contain sodium which diffuses from the first electrode 20 and/or is added into the layer 30 during deposition. The CIGS p-type compound semiconductor material layer 30 can also contain silver which is added into the layer 30 during deposition.

The n-type compound semiconductor material layer 40 includes at least a metal sulfide material as an n-doped semiconductor material. According to an aspect of the present disclosure, the compositional profile of the n-type compound semiconductor material layer 40 is altered from a homogeneous stoichiometric metal sulfide composition to provide enhanced performance for a photovoltaic cell.

In one embodiment, the metal sulfide material can be a metal-rich non-stoichiometric material that provides a higher conductivity than a stoichiometric metal sulfide. In another embodiment, the n-type compound semiconductor material layer 40 includes a stack including a metal sulfide layer and a metal sulfide-oxide layer. The thickness of the n-type compound semiconductor material layer 40 is typically less than the thickness of the p-type compound semiconductor material layer 30, and can be in a range from 30 nm to 100 nm, although lesser and greater thicknesses can also be employed. The junction between the p-type compound semiconductor material layer 30 and the n-type compound semiconductor material layer 40 is a p-n junction. The n-type compound semiconductor material layer 40 can be a material which is substantially transparent to at least part of the solar radiation. The n-type compound semiconductor material layer 40 is also referred to as a window layer or a buffer layer. The details of the compositional profile of the n-type compound semiconductor material layer 40 are further described below.

The second (e.g., front side or top) electrode 50 comprises one or more transparent conductive layers 50. The transparent conductive layer 50 is conductive and substantially transparent. The transparent conductive layer 50 can include one or more transparent conductive materials, such as ZnO, indium tin oxide (ITO), Al doped ZnO (“AZO”), Boron doped ZnO (“BZO”), or a combination or stack of higher resistivity AZO and lower resistivity ZnO, ITO, AZO and/or BZO layers. The second electrode 50 contacts an electrically conductive part (e.g., a metal wire or trace) of an interconnect structure (not shown). The interconnect structure may optionally contain one or more insulating sheets, such as optically transparent polymer sheets which support the electrically conductive part. The electrically conductive part electrically connects the first electrode 20 of one photovoltaic cell 10 to the second electrode 50 of an adjacent photovoltaic cell 10 in a photovoltaic panel (i.e., module). The interconnect may comprise the interconnect described in U.S. Pat. No. 8,912,429, issued Dec. 16, 2014, which is incorporated herein by reference in its entirety, or any other suitable interconnect that is used in photovoltaic panels.

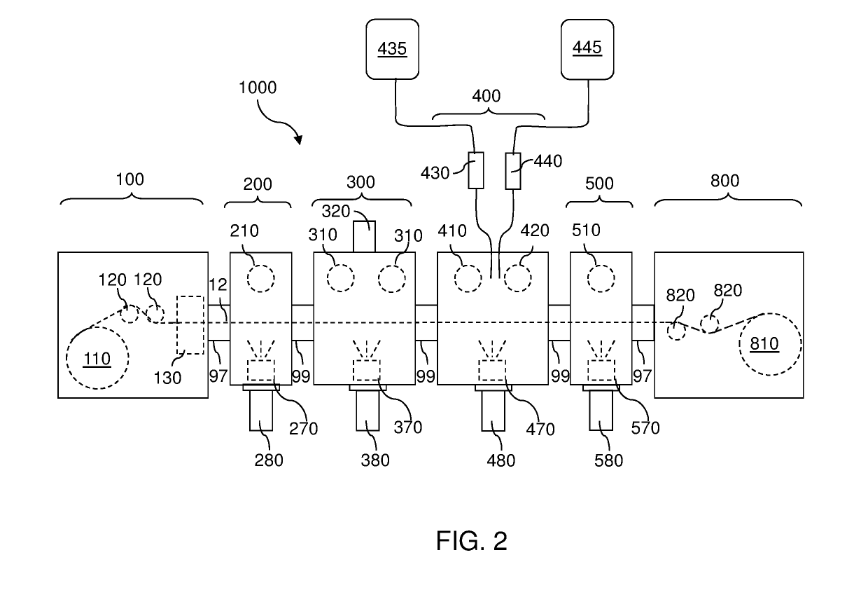

Referring to FIG. 2, an apparatus 1000 for forming the photovoltaic cell 10 illustrated in FIG. 1 is shown. The apparatus 1000 is an exemplary semiconductor device manufacturing apparatus, which is configured as a modular deposition apparatus. The apparatus 1000 can be used to manufacture the photovoltaic cell illustrated in FIG. 1. The apparatus 1000 includes an input unit 100, a first electrode deposition module 200, a p-type semiconductor deposition module 300, an n-type semiconductor deposition module 400, a second electrode deposition module 500, and an output unit 800 that are sequentially connected to accommodate a continuous flow of the substrate 12 in the form of a web foil substrate layer through the apparatus. The process modules (100, 200, 300, 400, 500) may comprise the process modules described in U.S. Pat. No. 9,303,316, issued on Apr. 5, 2016, incorporated herein by reference in its entirety, or any other suitable modules. The various process modules (200, 300, 400, 500) can be under vacuum by various vacuum pumps (280, 380, 480, 580), respectively. The various vacuum pumps (280, 380, 480, 580) can provide a suitable level of respective base pressure for each of the various process modules (200, 300, 400, 500), which may be in a range from 1.0×10⁻⁹ Torr to 1.0×10⁻² Torr, and preferably in range from 1.0×10⁻⁹ Torr to 1.0×10⁻⁵ Torr.

Each neighboring pair of process modules (200, 300, 400, 500) is interconnected employing a vacuum connection unit 99, which can include a vacuum tube and an optional slit valve that enables isolation while the substrate 12 is not present. The input unit 100 can be connected to the first electrode deposition module 200 employing a sealing connection unit 97. The last process module, such as the second electrode deposition module 500, can be connected to the output unit 800 employing another sealing connection unit 97.

The substrate 12 can be a metallic or polymer web foil that is fed into a system of process modules (200, 300, 400, 500) as a web for continuous deposition of material layers thereupon to form the photovoltaic cell 10. The substrate 12 can be fed from an entry side (i.e., at the input module 100), continuously move through the apparatus 1000 without stopping, and exit the apparatus 1000 at an exit side (i.e., at the output module 800). The substrate 12, in the form of a web, can be provided on an input spool 110 provided in the input module 100. Each of the process modules (200, 300, 400, 500) is configured to continuously feed the substrate 12 into a respective enclosure thereof through an entry opening (which may be located at the sealing connection unit 97 before the first electrode deposition module 200 or at a vacuum connection unit 99) and to continuously extract the substrate 12 from the respective enclosure through an exit opening (which may be located at a vacuum connection unit 99 or at the sealing connection unit 97 after the second electrode deposition module 500.

The substrate 12, as embodied as a metal or polymer web foil, is moved throughout the apparatus 1000 by input-side rollers 120, output-side rollers 820, and additional rollers (not shown) in the process modules (200, 300, 400, 500), vacuum connection units 99, or sealing connection units 97, or other devices. Additional guide rollers may be used. Some rollers (120, 820) may be bowed to spread the web (i.e., the substrate 12), some may move to provide web steering, some may provide web tension feedback to servo controllers, and others may be mere idlers to run the web in desired positions.

The input module 100 can be configured to allow continuous feeding of the substrate 12 by adjoining multiple foils by welding, stapling, or other suitable means. Rolls of substrates 12 can be provided on multiple input spools 110. A joinder device 130 can be provided to adjoin an end of each roll of the substrate 12 to a beginning of the next roll of the substrate 12. In one embodiment, the joinder device 130 can be a welder or a stapler. An accumulator device (not shown) may be employed to provide continuous feeding of the substrate 12 into the apparatus 1000 while the joinder device 130 adjoins two rolls of the substrate 12.

In one embodiment, the input module 100 may perform pre-processing steps. For example, a pre-clean process may be performed on the substrate 12 in the input module 100. In one embodiment, the substrate 12 may pass by a heater element array (not shown) that is configured to provide at least enough heat to remove water adsorbed on the surface of the substrate 12. In one embodiment, the substrate 12 can pass over a roller configured as a cylindrical rotary magnetron. In this case, the front surface of substrate 12 can be continuously cleaned by DC, AC, or RF sputtering as the substrate 12 passes around the roller/magnetron. The sputtered material from the substrate 12 can be captured on a disposable shield. Optionally, another roller/magnetron may be employed to clean the back surface of the substrate 12. In one embodiment, the sputter cleaning of the front and/or back surface of the substrate 12 can be performed with linear ion guns instead of magnetrons. Alternatively or additionally, a cleaning process can be performed prior to loading the roll of the substrate 12 into the input module 100. In one embodiment, a corona glow discharge treatment may be performed in the input module 100 without introducing an electrical bias.

The output module 800 can include an output spool 810, which winds the web embodying the photovoltaic cell 10. The photovoltaic cell 10 is the combination of the substrate 12 and the deposited layers (20, 30, 40, 50) thereupon.

In one embodiment, the substrate 12 may be oriented in one direction in the input module 100 and/or in the output module 800, and in a different direction in the process modules (200, 300, 400, 500). For example, the substrate 12 can be oriented generally horizontally in the input module 100 and the output module 800, and generally vertically in the process module(s) (200, 300, 400, 500). A turning roller or turn bar (not shown) may be provided to change the orientation of the substrate 12, such as between the input module 100 and the first electrode deposition module 200. In an illustrative example, the turning roller or the turn bar in the input module can be configured to turn the web substrate 12 from an initial horizontal orientation to a vertical orientation. Another turning roller or turn bar (not shown) may be provided to change the orientation of the substrate 12, such as between the last process module (such as the second electrode deposition module 500) and the output module 800. In an illustrative example, the turning roller or the turn bar in the input module can be configured to turn the web substrate 12 from the vertical orientation employed during processing in the process modules (200, 300, 400, 500) to a horizontal orientation.

The input spool 110 and optional output spool 810 may be actively driven and controlled by feedback signals to keep the substrate 12 in constant tension throughout the apparatus 1000. In one embodiment, the input module 100 and the output module 800 can be maintained in the air ambient at all times while the process modules (200, 300, 400, 500) are maintained at vacuum during layer deposition.

Each of the various process modules (200, 300, 400, 500) can deposit a respective material layer to form the photovoltaic cell 10 (shown in FIG. 1) as the substrate 12 passes through the various process modules (200, 300, 400, 500) sequentially.

Optionally, one or more additional process modules (not shown) may be added between the input module 100 and the first electrode deposition module 200 to sputter a back side protective layer on the back side of the substrate 12 before deposition of the first electrode 20 in the first electrode deposition module 200. Further, one or more barrier layers may be sputtered over the front surface of the substrate 12 prior to deposition of the first electrode 20. Alternatively or additionally, one or more process modules (not shown) may be added between the first electrode deposition module 200 and the p-type semiconductor deposition module 300 to sputter one or more adhesion layers between the first electrode 20 and the p-type compound semiconductor material layer 30 including a copper-indium-gallium-chalcogenide material.

The first electrode deposition module 200 includes at least one metal sputtering target 210, which includes the material of the first electrode 20 in the photovoltaic cell 10 illustrated in FIG. 1. A first heater element 270 can be provided to heat the web substrate 12 to an optimal temperature for deposition of the first electrode 20. In one embodiment, a plurality of metal sputtering targets 210 and a plurality of first heater elements 270 may be employed in the first electrode deposition module 200. In one embodiment, the at least one metal sputtering target 210 can be mounted on dual cylindrical rotary magnetron(s), or planar magnetron(s) sputtering sources, or RF sputtering sources. In one embodiment, the at least one metal sputtering target 210 can include a molybdenum target, a molybdenum-sodium, and/or a molybdenum-sodium-oxygen target, as described in U.S. Pat. No. 8,134,069, incorporated herein by reference in its entirety.

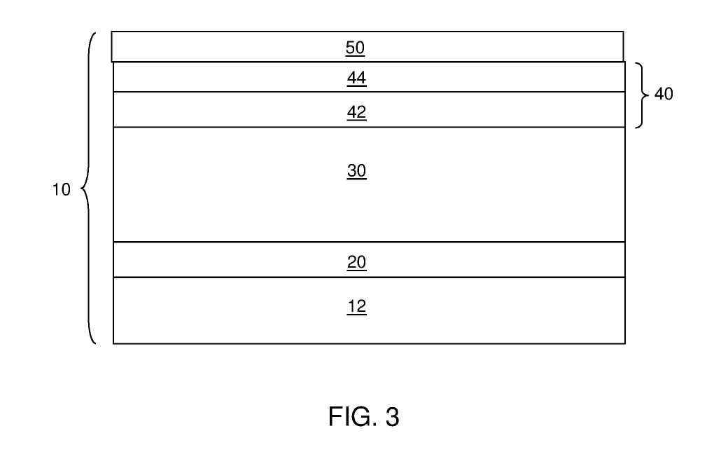

Referring to FIGS. 2 and 3, the portion of the substrate 12 on which the first electrode 20 is deposited is moved into the p-type semiconductor deposition module 300. The p-type semiconductor deposition module 300 includes in an enclosed chamber, i.e., in an enclosure. The p-type semiconductor deposition process module 300 is configured to receive the substrate 12 through an entrance and to extract the substrate through an exit, and includes at least one metal-alloy sputtering target 310. In one embodiment, each metal-alloy sputtering target 310 can include a respective metallic component target that includes an alloy of copper, indium and gallium (“CIG” alloy), and optionally any other metal (e.g., silver) that can enhance properties of the deposited p-type compound semiconductor layer 30. The p-type semiconductor deposition process module 300 includes a chalcogen source 320, and is configured for deposition of a p-type compound semiconductor material layer comprising copper, indium, gallium, and a chalcogen on the substrate 12 during transit therethrough.

The at least one metal-alloy sputtering target 310 can simultaneously sputter copper, indium, and gallium within the enclosure of the p-type semiconductor deposition module 300. The substrate 12 is continuously fed into the enclosed chamber, and is continuously extracted out of the enclosed chamber.

A p-doped copper-indium-gallium-chalcogenide material is deposited to form the p-type compound semiconductor material layer 30. In one embodiment, the p-doped copper-indium-gallium-chalcogenide material can be deposited employing reactive alternating current (AC) magnetron sputtering in a sputtering atmosphere that includes argon and a chalcogen-containing gas at a reduce pressure. In one embodiment, multiple sputtering targets 310, such as CIG alloy targets 310 may be used.

As used herein, the “metallic components” of a copper-indium-gallium-chalcogenide material refers to the non-chalcogenide components of the copper-indium-gallium-chalcogenide material, i.e., copper, indium, and gallium. The metallic component targets of the at least one metal-alloy sputtering target 310 can include alloys of at least two metallic materials in the copper-indium-gallium-chalcogenide material to be deposited, such as CIG alloys. More than two types of targets may be used.

The enclosure of the p-type semiconductor deposition module 300 can be configured with at least one source for providing an ambient including at least one chalcogen-containing gas therein. Specifically, at least one chalcogen-containing gas source 320, such as a selenium evaporator can be provided on the p-type semiconductor deposition module 300 to provide a chalcogen-containing gas into the p-type semiconductor deposition module 300. The chalcogen-containing gas provides chalcogen atoms (e.g., Se atoms) that are incorporated into the deposited copper-indium-gallium-chalcogenide material. In one embodiment, multiple instances of the chalcogen-containing gas source 320 can be provided on the p-type semiconductor deposition module 300.

The p-type semiconductor deposition module 300 can be provided with multiple sets of copper-indium-gallium-chalcogenide material deposition units. As many copper-indium-gallium-chalcogenide material deposition units can be provided along the path of the substrate 12 as is needed to achieve the desired thickness for the p-doped copper-indium-gallium-chalcogenide material. The number of second vacuum pumps 380 may, or may not, coincide with the number of the deposition units. The number of second heater elements 370 may, or may not, be commensurate with the number of the deposition units.

The chalcogen-containing gas source 320 includes a source material for the chalcogen-containing gas. For example, if a copper-indium-gallium-selenide (CIGS) material is to be deposited for the p-type compound semiconductor material layer 30, the chalcogen-containing gas may be selected, for example, from hydrogen selenide (H₂Se) and selenium vapor. In case the chalcogen-containing gas is hydrogen selenide, the chalcogen-containing gas source 320 can be a cylinder of hydrogen selenide. In case the chalcogen-containing gas is selenium vapor, the chalcogen-containing gas source 320 can be an effusion cell that can be heated to generate selenium vapor.

The second heater elements 370 can include at least one radiation heater element. The second heater elements 370 maintain the temperature of the web substrate 12 at a target deposition temperature. A temperature control system including at least one temperature sensor can be connected to the second heater elements 370 so that the temperature of the substrate 12 can be maintained in a range from 550 degrees Celsius to 900 degrees Celsius during deposition of the alloy of copper, indium, gallium, and the at least one chalcogen on the substrate 12. For example, the temperature of the substrate 12 may be in a range from 600 degrees to 800 degrees, such as from 625 degrees to 740 degrees, during deposition of the alloy of copper, indium, gallium, and at the at least one chalcogen.

The chalcogen incorporation during deposition of the copper-indium-gallium-chalcogenide material determines the properties and quality of the copper-indium-gallium-chalcogenide material in the p-type compound semiconductor material layer 30. When the chalcogen-containing gas is supplied in the gas phase at an elevated temperature, the chalcogen atoms from the chalcogen-containing gas can be incorporated into the deposited film by absorption and subsequent bulk diffusion. This process is referred to as chalcogenization, in which complex interactions occur to form the copper-indium-gallium-chalcogenide material. The p-type doping in the p-type compound semiconductor material layer 30 is induced by controlling the degree of deficiency of the amount of chalcogen atoms with respect the amount of non-chalcogen atoms (such as copper atoms, indium atoms, and gallium atoms in the case of a CIGS material) deposited from the metallic component targets of the at least one metal-alloy sputtering target 310.

In one embodiment, the composition of the sputtered material from the metallic component targets can be gradually changed along the path of the substrate 12 so that a graded copper-indium-gallium-chalcogenide material can be deposited in the p-type semiconductor deposition module 300. For example, the atomic ratio of gallium to gallium plus indium and/or the atomic ratio of copper to group III metals of the deposited CIGS material can increase and/or decrease as the substrate 12 progresses through the p-type semiconductor deposition module 300, as described for example in U.S. patent application Ser. No. 15/403,434 filed on Jan. 11, 2017 and incorporated by reference herein in its entirety.

In one embodiment, the total number of the metal-alloy sputtering targets 310 may be in a range from 3 to 20. In an illustrative example, the composition of the deposited copper-indium-gallium-chalcogenide material can be graded such that the band gap of the p-doped CIGS material changes gradually or in discrete steps with distance from the interface between the first electrode 20 and the p-type compound semiconductor material layer 30.

The p-type semiconductor deposition module 300 can include multiple sputtering regions that can be employed to sputter different metallic alloys. The p-type semiconductor deposition module 300 can deposit the p-type compound semiconductor material layer 30 as a polycrystalline material layer. The average grain size can increase with distance from the first electrode 20 in the p-type compound semiconductor material layer 30. In one embodiment, large average grain sizes in a range from 1 micron to 4 microns can be provided on the surface of the p-type compound semiconductor material layer 30, which forms the interface with the n-type compound semiconductor material layer 40 to be subsequently deposited.

While the present disclosure is described employing an embodiment in which CIG alloy sputtering targets 310 are used, embodiments are expressly contemplated herein in which each, or a subset, of the metallic component targets is replaced with a pair of two sputtering targets (such as a copper target and an indium-gallium alloy target), or a set of three sputtering targets (such as a copper target, an indium target, and a gallium target).

The portion of the substrate 12 on which the first electrode 20 and the p-type compound semiconductor material layer 30 are deposited is subsequently passed into the n-type semiconductor deposition module 400. An n-doped semiconductor material is deposited in the n-type semiconductor deposition module 400 to form the n-doped semiconductor layer 40 illustrated in the photovoltaic cell 10 of FIG. 1. The n-type semiconductor deposition module 400 can include, for example, at least one n-type semiconductor sputtering target (410, 420) (which includes an n-type semiconductor target such as a CdS target) and a magnetron (not expressly shown). Each of the at least one n-type semiconductor sputtering target (410, 420) can include, for example, a rotating AC magnetron, an RF magnetron, or a planar magnetron. A heater element 470 may be located in the process module 400.

The n-type semiconductor deposition module 400 is configured to receive the substrate 12 from the p-type semiconductor deposition module 300 through an entrance and to extract the substrate 12 through an exit. The n-type semiconductor deposition module 400 includes at least one n-type semiconductor sputtering target (410, 420) configured for deposition of at least one n-type metal sulfide layer on the substrate 12 during transit of the substrate 12 through the n-type semiconductor deposition module 400. One (or more) of the at least one n-type semiconductor sputtering targets (410, 420) includes a metal sulfide target having a non-stoichiometric composition in which a metal-to-sulfur atomic ratio is greater than 1, such as in a range from 1.05 to 1.20, such as from 1.08-1.17 and/or from 1.10 to 1.15.

The n-type compound semiconductor material layer 40 of FIG. 1 can include the metal sulfide layer having a non-stoichiometric composition in which a metal-to-sulfur atomic ratio is greater than 1, such as in a range from 1.05 to 1.20, such as from 1.08-1.17 and/or from 1.10 to 1.15. The thickness of the n-type compound semiconductor material layer 40 can be in a range from 30 nm to 100 nm, although lesser and greater thicknesses can also be employed. The n-type compound semiconductor material layer 40 includes at least one n-type metal sulfide layer that comprises a material selected from cadmium sulfide, zinc sulfide, and cadmium zinc sulfide.

The non-stoichiometric metal sulfide of the n-type compound semiconductor material layer 40 can be a metal-rich cadmium sulfide (e.g., a cadmium-rich cadmium sulfide) or a metal-rich zinc sulfide (e.g., a zinc-rich zinc sulfide). The cadmium-rich cadmium sulfide can have a chemical composition of CdₓS (which can include 0 to 1 atomic percent oxygen) in which x is greater than 1, such as in a range from 1.05 to 1.20. Resistivity of stoichiometric cadmium sulfide having the metal-to-sulfur atomic ratio of 1.0 is about 3.4×10³ Ω-cm. Resistivity of non-stoichiometric cadmium sulfide having a chemical composition of CdₓS decreases with an increasing value of x greater than 1.0. For example, resistivity of Cd_{1.06}S is about 3.4×10² Ω-cm, and resistivity of Cd_{1.09}S is about 8.0×10¹ Ω-cm. Without wishing to be bound by a particular theory, it is believed that the decrease in resistivity, i.e., the increase in electrical conductivity, of CdₓS with an increasing value of x greater than 1.0 may be due to creation of sulfur vacancies and/or generation of excess electrons in the conduction band of the CdₓS compound semiconductor.

Without wishing to be bound by a particular theory, it is believed that similar phenomenon may occur with a metal-rich zinc sulfide. Resistivity of stoichiometric zinc sulfide having the metal-to-sulfur atomic ratio of 1.0 is about 4×10⁴ Ω-cm. Similar to the metal-rich cadmium sulfide, it is believed that the decrease in resistivity of ZnₓS with an increasing value of x greater than 1.0 may be due to creation of sulfur vacancies and/or generation of excess electrons in the conduction band of the ZnₓS compound semiconductor.

According to a first embodiment of the present disclosure, the entirety of the n-type compound semiconductor material layer 40 can include a same metal sulfide material with, or without, a concentration gradient therein as illustrated in FIG. 1. In this case, the n-type compound semiconductor material layer 40 includes one n-type metal sulfide material selected from cadmium sulfide, zinc sulfide, and cadmium zinc sulfide.

In one embodiment, the entirety of the n-type compound semiconductor material layer 40 of FIG. 1 can have a non-stoichiometric composition in which a metal-to-sulfur atomic ratio is greater than 1, such as in a range from 1.05 to 1.20. In one embodiment, the entirety of the n-type compound semiconductor material layer 40 can have a homogeneous non-stoichiometric composition throughout. In this case, the at least one n-type semiconductor sputtering target (410, 420) of FIG. 2 can be a single sputtering target, such as a single non-stoichiometric (i.e., metal rich) semiconductor sputtering target, or can be a plurality of sputtering targets, such as multiple semiconductor sputtering targets having the same composition.

In another embodiment, the n-type compound semiconductor material layer 40 if FIG. 1 can have a composition gradient along the direction of film thickness, i.e., along the direction perpendicular to a top surface of the n-type metal sulfide layer. The metal-to-sulfur atomic ratio in portions proximal to (i.e., closer to) the p-doped compound semiconductor material layer 30 can be in a range from 1.05 to 1.15, and the metal-to-sulfur atomic ratio in portions distal from (i.e., father form) the p-doped compound semiconductor material layer 30 can be greater than in the proximal portions, such as in a range from 1.10 to 1.20, such that the metal-to-sulfur atomic ratio generally increases with distance from the p-doped compound semiconductor material layer 30 within the n-type compound semiconductor material layer 40. In this case, the at least one n-type semiconductor sputtering target (410, 420) of FIG. 2 can include a first non-stoichiometric metal sulfide target 410 having a metal-to-sulfur atomic ratio in a range from 1.05 to 1.15, and a second non-stoichiometric metal sulfide target 420 having a metal-to-sulfur atomic ratio which is greater than that of target 410, such as a ratio in a range from 1.10 to 1.20.

Alternatively, the n-type compound semiconductor material layer 40 of FIG. 1 can include a stack, from bottom to top, of a substantially stoichiometric metal sulfide layer and non-stoichiometric metal sulfide layer. As used herein, a “substantially stoichiometric metal sulfide layer” refers to a metal sulfide layer in which the metal-to-sulfur atomic ratio is exactly 1 or about 1, such as within a range from 0.95 to 1.03. In this case, at least one n-type semiconductor sputtering target (410, 420) of FIG. 2 comprises a plurality of n-type semiconductor sputtering targets having different metal-to-sulfur atomic ratios. The second process module is configured to deposit the n-type metal sulfide layer with a gradient in a metal-to-sulfur atomic ratio therein along the direction perpendicular to the top surface of the n-type metal sulfide layer, i.e., the stack of the substantially stoichiometric metal sulfide layer and the non-stoichiometric metal sulfide layer that constitutes the n-type compound semiconductor layer 40 of FIG. 1.

The metal-to-sulfur atomic ratio in the substantially stoichiometric metal sulfide layer can be in a range from 0.95 to 1.03, and the metal-to-sulfur atomic ratio in the non-stoichiometric metal sulfide layer can be in a range from 1.05 to 1.20 such that the metal-to-sulfur atomic ratio generally increases with distance from the p-doped compound semiconductor material layer 30 within the n-type compound semiconductor material layer 40. In this case, the at least one n-type semiconductor sputtering target (410, 420) of FIG. 2 can include a first substantially stoichiometric metal sulfide sputtering target 410 having a metal-to-sulfur atomic ratio in a range from 0.95 to 1.03, and a second non-stoichiometric metal sulfide sputtering target 420 having a metal-to-sulfur atomic ratio which is greater than that of target 410, such as a ratio in a range from 1.05 to 1.20.

The n-type semiconductor deposition module 400 is configured to deposit a substantially stoichiometric metal sulfide layer as a first sublayer of the n-type metal sulfide layer by sputtering the first substantially stoichiometric metal sulfide sputtering target 410, and to subsequently deposit a non-stoichiometric metal sulfide as a second sublayer of the n-type metal sulfide layer by sputtering the second non-stoichiometric metal sulfide sputtering target 420. The n-type metal sulfide layer, i.e., the n-type compound semiconductor material layer 40 of FIG. 1, is deposited such that the metal-to-sulfur atomic ratio in the n-type metal sulfide layer increases with distance from the p-type compound semiconductor material layer 30 either continuously or in a stepwise manner, i.e., in at least one step.

The n-type metal sulfide layer can be deposited as a polycrystalline material. In one embodiment, a high crystalline quality, as measured by the average grain size within the surface of growth, can be achieved by inducing epitaxial alignment between the polycrystalline material of the n-type compound semiconductor material layer 40 and the polycrystalline material of the p-type compound semiconductor material layer 30. By inducing epitaxial alignment of the polycrystalline material of the n-type compound semiconductor material layer 40 with the polycrystalline material of the p-type compound semiconductor material layer 30, the average grain size of the n-type compound semiconductor material layer 40 can be at least as large throughout the n-type compound semiconductor material layer 40 as the average grain size of the surface portion of the p-type compound semiconductor material layer 30 that contacts the n-type compound semiconductor material layer 40. In one embodiment, a predominant portion (i.e., majority) of grain boundaries of the n-type metal sulfide layer can coincide with grain boundaries of the p-type compound semiconductor material layer 30 at the interface between the n-type metal sulfide layer 40 and the p-type compound semiconductor material layer 30.

To facilitate epitaxial alignment of the n-type compound semiconductor material layer 40 with the p-type compound semiconductor material layer 30, an oxidizer gas and a hydrogen-containing gas can be flowed simultaneously or alternately into the processing chamber of the n-type semiconductor deposition module 400 during the sputtering process of the n-type semiconductor deposition module 400. Epitaxial alignment between the n-type metal sulfide layer and the p-type compound semiconductor material layer 30 can be induced during deposition of the n-type metal sulfide layer by the combination of the oxidizer gas and the hydrogen-containing gas.

In one embodiment, an oxidizer gas supply system (430, 435) can be connected to the n-type semiconductor deposition module 400. The oxidizer gas supply system (430, 435) can include, for example, an oxidizer gas flow controller 430 and an oxidizer gas supply tank (e.g., oxygen tank) 435. The oxidizer gas supply system (430,435) can be configured to flow an oxidizer gas (such as oxygen) into the n-type semiconductor deposition module 400 during deposition of the n-type metal sulfide layer by the sputtering process. Further, a hydrogen-containing gas supply system (440, 445) can be connected to the n-type semiconductor deposition module 400. The hydrogen-containing gas supply system (440, 445) can include, for example, a hydrogen-containing gas flow controller 440 and a hydrogen-containing gas supply tank 445 (e.g., hydrogen tank). The hydrogen-containing gas supply system (440, 445) can be configured to flow a hydrogen-containing gas (such as hydrogen) into the n-type semiconductor deposition module 400 during deposition of the n-type metal sulfide layer by the sputtering process. In one embodiment, the hydrogen-containing gas supply system (440, 445) and the oxidizer gas supply system (430, 435) can be configured to maintain a partial pressure of the hydrogen-containing gas higher than a partial pressure of the oxidizer gas.

Without wishing to be bound by a particular theory, it is believed that addition of oxygen gas to the physical vapor deposition process may modify the crystallinity of the resulting n-type metal sulfide layer, and thus, controls the amount of interdiffusion of species from the CIGS material into the n-type metal sulfide material. By varying the amount of oxygen in the physical vapor deposition process, the crystallinity and the grain size of the deposited n-type metal sulfide material continuously changes from a fully amorphous material in the case of a high oxygen partial pressure (for example, greater than about 1.5 mTorr) to a fully epitaxial material in the case of substantially zero partial pressure (for example, less than 0.1 mTorr). The addition of oxygen alone can modify the electronic properties of a deposited cadmium sulfide film.

Introduction of hydrogen in addition to oxygen can provide simultaneous tunability of crystallinity and charge carrier mobility. According to an embodiment of the present disclosure, oxygen gas can be added into a reactive magnetron sputter deposition process for cadmium sulfide at flow levels from about 1 sccm (standard cubic centimeter per minute) to about 100 sccm (corresponding to a partial pressure from about 0.025 mTorr to about 2.5 mTorr) to modify the crystal structure and the composition of the deposited cadmium sulfide material to reduce or prevent copper diffusion through the cadmium sulfide material. According to an embodiment of the present disclosure, hydrogen gas can be added into the reactive magnetron sputter deposition process concurrently with addition of the oxygen gas at flow levels from about 1 sccm to about 200 sccm (corresponding to a partial pressure from about 0.025 mTorr to about 5 mTorr) to modulate the oxygen content in the cadmium sulfide material and to increase the mobility of charge carriers within the cadmium sulfide material.

In one embodiment, the partial pressure of the oxidizer gas can be maintained in a range from 0.025 mTorr to 1.0 mTorr in the n-type semiconductor deposition module 400 during deposition of the n-type metal sulfide layer by the sputtering process. The partial pressure of the hydrogen-containing gas can be maintained in a range from 0.05 mTorr to 2.0 mTorr, and can be greater than the partial pressure of the oxidizer gas, in the n-type semiconductor deposition module 400 during deposition of the n-type metal sulfide layer by the sputtering process. In this case, the hydrogen-containing gas supply system (440, 445) and the oxidizer gas supply system (430, 435) are configured to maintain a partial pressure of the hydrogen-containing gas higher than a partial pressure of the oxidizer gas.

In case the n-type metal sulfide layer includes cadmium sulfide, optimal levels of net oxygen and hydrogen addition to the sputtering chamber ambient induce deposition of an epitaxial cadmium sulfide material having a hexagonal phase over the CIGS material. At the deposition temperature employed to deposit the epitaxial cadmium sulfide material, cadmium atoms in the epitaxial cadmium sulfide material may diffuse into the CIGS material, and copper atoms in the CIGS material may diffuse into the epitaxial cadmium sulfide material, thereby replacing a portion of the cadmium atoms with copper atoms and vice-versa at an interface between the CIGS material and the deposited epitaxial cadmium sulfide material having the hexagonal phase. The replacement of the cadmium atoms with the copper atoms generates the hexagonal phase copper cadmium sulfide layer.

According to a second embodiment of the present disclosure, the n-type compound semiconductor material layer 40 can include at least two sulfide materials as illustrated in FIG. 3. In this case, the n-type compound semiconductor material layer 40 includes at least two n-type metal sulfide materials selected from cadmium sulfide, zinc sulfide, and cadmium zinc sulfide. Each n-type metal sulfide material forms a sublayer of the n-type compound semiconductor material layer 40. For example, the n-type compound semiconductor material layer 40 can include a first n-type metal sulfide sublayer 42 and a second n-type metal sulfide sublayer 44. A stack of the first n-type metal sulfide sublayer 42 and the second n-type metal sulfide sublayer 44 constitutes an n-type metal sulfide layer (42, 44).

In one embodiment, the first n-type metal sulfide sublayer 42 can be the same as any of the n-type metal sulfide sublayers described above. As such, the first n-type metal sulfide sublayer 42 may be homogeneous and consist of an n-type metal sulfide material in which the metal-to-sulfur atomic ratio is greater than 1, such as between 1.05 and 1.20, may be inhomogeneous and include an n-type metal sulfide material in which the metal-to-sulfur atomic ratio is greater than 1, such as between 1.05 and 1.20 with a gradient of the metal-to-sulfur atomic ratio, or may include a layer stack of a substantially stoichiometric metal sulfide layer and an n-type metal sulfide layer in which the metal-to-sulfur atomic ratio is greater than 1, such as between 1.05 and 1.20 with, or without, a gradient in the metal-to-sulfur atomic ratio. In this case, the second n-type metal sulfide sublayer 44 can include a different metal than the metal within the first n-type metal sulfide sublayer 42.

In an alternative embodiment, second n-type metal sulfide sublayer 44 can include oxygen in addition to sulfur, such that at least 20 atomic percent, such as 20 to 80 atomic percent of the sulfur is substituted by oxygen. Thus, the second n-type metal sulfide sublayer 44 can include zinc oxysulfide, cadmium oxysulfide or zinc cadmium oxysulfide. In this embodiment, more oxygen is supplied in the downstream portion of the module 400 adjacent to target 420 than in the upstream portion of the module 400 adjacent to target 410. As described above, the first n-type metal sulfide sublayer 42 can also include one atomic percent oxygen or less as a residual, background or unavoidable impurity.

The thickness of the first n-type metal sulfide sublayer 42 may be reduced with respect to the n-type metal sulfide layer of the first embodiment so that the thickness of the n-type compound semiconductor material layer 40 of the second embodiment is in a range from 30 nm to 100 nm. For example, the thickness of the first n-type metal sulfide sublayer 42 can be in a range from 3 nm to 70 nm. The metal-to-sulfur atomic ratio within the second n-type metal sulfide sublayer 44 can be in a range from 0.95 to 1.20. In one embodiment, the metal-to-sulfur atomic ratio within the second n-type metal sulfide sublayer 44 can be in a range from 0.95 to 1.03. In another embodiment, the metal-to-sulfur atomic ratio within the second n-type metal sulfide sublayer 44 can be greater than 1, such as in a range from 1.05 to 1.20, such as from 1.08-1.17 and/or from 1.10 to 1.15.

In another embodiment, the first n-type metal sulfide sublayer 42 may be formed with a metal-to-sulfur atomic ratio in a range from 0.95 to 1.03. The thickness of the first n-type metal sulfide sublayer 42 can be in a range from 3 nm to 70 nm. In this case, the second n-type metal sulfide sublayer 44 can include a different metal than the metal within the first n-type metal sulfide sublayer 42. The metal-to-sulfur atomic ratio within the second n-type metal sulfide sublayer 44 can be in a range from 1.05 to 1.20, such as from 1.08-1.17 and/or from 1.10 to 1.15. The combined thicknesses of the first n-type metal sulfide sublayer 42 and the second n-type metal sulfide sublayer 44 can be in a range from 30 nm to 100 nm, although lesser and greater thicknesses can also be employed.

In the second embodiment, the at least one n-type semiconductor sputtering target (410, 420) of FIG. 2 can include at least one first n-type semiconductor sputtering target 410 that includes a respective first metal sulfide material (e.g., cadmium sulfide) for depositing the first n-type metal sulfide sublayer 42, and at least one second n-type semiconductor sputtering target 420 containing different a respective second metal sulfide material (e.g., zinc sulfide) for depositing the second n-type metal sulfide sublayer 44.

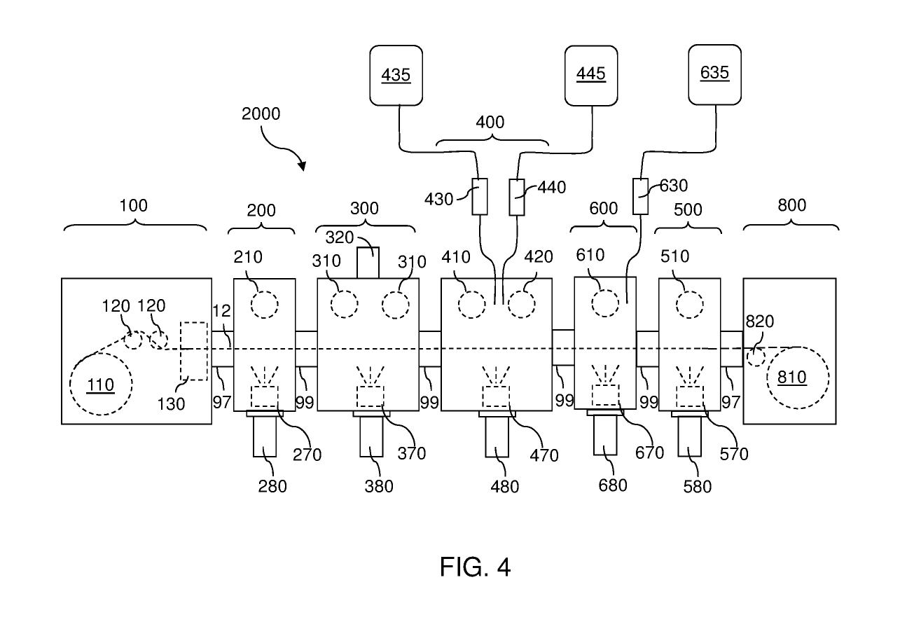

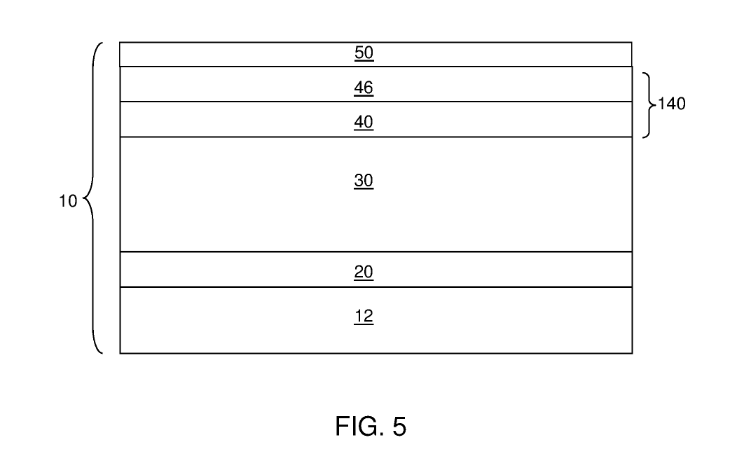

FIG. 4 illustrates an apparatus 2000 according to an alternative embodiment for manufacturing a photovoltaic cell of the third embodiment shown in FIG. 5. The apparatus 2000 is an exemplary semiconductor device manufacturing apparatus, which is configured as a modular deposition apparatus. The apparatus 2000 is derived from the apparatus 1000 illustrated in FIG. 2 by providing an additional metal sulfide-oxide deposition module 600 between the n-type semiconductor deposition module 400 and the second electrode deposition module 500.

During operation of the apparatus 2000, the processing steps can be performed in the various modules up to the processing steps performed in the n-type semiconductor deposition module 400 according to the first or second embodiment. The substrate 12 is transferred from the n-type semiconductor deposition module 400 into the metal sulfide-oxide deposition module 600 through a vacuum connection unit 99 between the n-type semiconductor deposition module 400 and the metal sulfide-oxide deposition module 600.

The metal sulfide-oxide deposition module 600 is configured to receive the substrate 12 from the n-type semiconductor deposition module 400 through an entrance of the metal sulfide-oxide deposition module 600 and to extract the substrate 12 through an exit of the metal sulfide-oxide deposition module 600. The metal sulfide-oxide deposition module 600 includes a metal sulfide sputtering target 610 containing a metal sulfide target and an oxidizer gas supply system (630, 635) that are configured for deposition of a conductive metal sulfide-oxide compound on the substrate 12 during transit of the substrate 12 through the metal sulfide-oxide deposition module 600.

A heater element 670 can be provided to heat the web substrate 12 to an optimal temperature for deposition of the conductive metal sulfide-oxide compound. A vacuum pump 680 can be provided on the metal sulfide-oxide deposition module 600 to maintain a base pressure within the enclosure of the metal sulfide-oxide deposition module 600. In one embodiment, the metal sulfide sputtering target 610 can be mounted on dual cylindrical rotary magnetron(s), or planar magnetron(s) sputtering sources, or RF sputtering sources.

The metal sulfide-oxide deposition module 600 sputters a metal sulfide material from the metal sulfide target, which may include a stoichiometric metal sulfide or a non-stoichiometric metal sulfide. The metal sulfide material may be selected from cadmium sulfide, zinc sulfide, and cadmium zinc sulfide. The metal sulfide material as sputtered from the metal sulfide target may, or may not, be metal-rich, i.e., have a metal-to-sulfur atomic ratio or about 1 or greater than 1. The oxidizer gas supply system (630, 635) can include, for example, an oxidizer gas flow controller 630 and an oxidizer gas supply tank 635. The oxidizer gas supply tank 635 can be the same tank as tank 435 or a separate tank. The oxidizer gas supply system (630, 635) supplies an oxidizing gas such as oxygen, ozone, or nitrous oxide. For example, the oxidizer gas supply system (630, 635) can supply oxygen gas into the metal sulfide-oxide deposition module 600. A conductive metal sulfide-oxide compound can be deposited on the n-type metal sulfide layer(s) in the metal sulfide-oxide deposition module 600 by a sputtering process employing the metal sulfide target and the oxidizing ambient within the metal sulfide-oxide deposition module 600.

Referring to FIG. 5, a third exemplary photovoltaic cell 10 is illustrated. The third exemplary photovoltaic cell 10 can be formed by depositing a first electrode 20 and a p-type compound semiconductor material layer 30 as in the first and second embodiments. An n-type metal sulfide layer 40 is formed in the same manner as in the first or second embodiment. The n-type metal sulfide layer 40 can include the n-type compound semiconductor material layer 40 of FIG. 1 (which is a single metal sulfide layer with or without concentration gradient), or the n-type compound semiconductor material layer 40 of FIG. 3 (which is a stack of at least two n-type metal sulfide sublayers (42, 44)). The n-type metal sulfide layer 40 can be formed in the n-type semiconductor deposition module 400 as described above.

A metal sulfide-oxide compound layer 46 is deposited on the n-type metal sulfide layer(s) 40 by a sputtering process employing the metal sulfide target and the oxidizing ambient within the metal sulfide-oxide deposition module 600, as illustrated in FIGS. 4 and 5. In one embodiment, the metal sulfide-oxide compound layer 46 can be an electrically conductive metal sulfide-oxide compound layer that has a greater electrical conductivity than a stoichiometric metal sulfide including the same metallic element as the metal sulfide-oxide compound layer 46. For example, the metal sulfide-oxide compound layer 46 can be zinc oxysulfide, cadmium oxysulfide or zinc cadmium oxysulfide.

In one embodiment, the conductive metal sulfide-oxide compound layer 46 can have a formula of MₓS_{y}O_{1-y}. M can be Cd, Zn, or a mixture of Cd and Zn. The value of x can be in a range from 0.95 to 1.20. The value of y can be in a range from 0.20 to 0.80, such as from 0.30 to 0.70 and/or from 0.40 to 0.60. In other words, the metal sulfide-oxide compound layer 46 can be stoichiometric or non-stoichiometric (e.g., metal rich) and can have 20 to 80 atomic percent of sulfur substituted by oxygen. The partial pressure of the oxidizing gas can be set at a level that provides the target stoichiometry for the conductive metal sulfide-oxide compound. In one embodiment, the oxidizing gas can be oxygen, and the partial pressure of oxygen can be in a range from 1 mTorr to 100 mTorr, although lesser and greater partial pressures may also be employed. The thickness of the conductive metal sulfide-oxide compound layer 46 can be in a range from 3 nm to 60 nm, although lesser and greater thicknesses can also be employed.

The stack of the n-type compound semiconductor material layer 40 and the conductive metal sulfide-oxide compound layer 46 constitutes an n-type material layer 140, which forms a p-n junction structure in conjunction with the p-type compound semiconductor material layer 30. In one embodiment, the n-type material layer 140 can have a thickness in a range from 30 nm to 150 nm, although lesser and greater thicknesses can also be employed.

Alternatively, as described above, the separate module 600 for forming the conductive metal sulfide-oxide compound layer 46 can be omitted. Instead, both layers 40 and 46 can be formed in the same module 400 with more oxygen supplied in the downstream portion of module 400 adjacent to target 420 than in the upstream portion of module adjacent to target 410.

Referring collectively to FIGS. 2 and 4, the portion of the substrate 12, on which the first electrode 20, the p-type compound semiconductor material layer 30, and the n-doped semiconductor layer 40 and the optional conductive metal sulfide-oxide compound layer 46 are deposited, is subsequently passed into the second electrode deposition module 500. A transparent conductive oxide material is deposited in the second electrode deposition module 500 to form the second electrode comprising a transparent conductive layer 50 illustrated in the photovoltaic cells 10 of FIGS. 1, 3, and 5. The second electrode deposition module 500 can include, for example, a conductive oxide sputtering target 510 and a magnetron (not expressly shown). The conductive oxide sputtering target 510 can include, for example, a ZnO, AZO or ITO target and a rotating AC magnetron, an RF magnetron, or a planar magnetron. A transparent conductive oxide layer 50 is deposited over the material stack (30, 40) including the p-n junction. In one embodiment, the transparent conductive oxide layer 50 can comprise a material selected from tin-doped indium oxide, aluminum-doped zinc oxide, and zinc oxide. In one embodiment, the transparent conductive oxide layer 50 can have a thickness in a range from 60 nm to 1,800 nm.

Subsequently, the web substrate 12 passes into the output module 800. The substrate 12 can be wound onto the output spool 810 (which may be a take up spool), or can be sliced into photovoltaic cells using a cutting apparatus (not shown).

A photovoltaic cell 10 formed by the methods of the present disclosure can include an n-type compound semiconductor material layer 40 and the optional conductive metal sulfide-oxide compound layer 46 described above.

In some embodiments shown in FIGS. 1, 3 and 5, the photovoltaic cell 10 includes a first electrode 20 located over a substrate 12, a p-type compound semiconductor material layer 30 located on the first electrode layer and comprising copper, indium, gallium and a chalcogen (e.g., CIGS, such as sodium and/or silver doped CIGS), a polycrystalline metal rich metal sulfide n-type compound semiconductor material layer 40 (e.g., metal rich cadmium sulfide) located on the p-type compound semiconductor material layer 30, and a second electrode 50 located on the metal rich metal sulfide n-type compound semiconductor material layer 40.

Another embodiment photovoltaic cell 10 illustrated in FIG. 5, comprises the first electrode 20 located over the substrate 12, the p-type compound semiconductor material layer 30 located on the first electrode layer and comprising copper, indium, gallium and a chalcogen (e.g., doped or undoped CIGS), a metal sulfide n-type compound semiconductor material layer 40 (e.g., stoichiometric or metal rich cadmium sulfide) located on the p-type compound semiconductor material layer 30, a conductive metal sulfide-oxide compound layer 46 located on the metal sulfide n-type compound semiconductor material layer 40, and a second electrode 50 located on the conductive metal sulfide-oxide compound layer 46.

The n-type compound semiconductor material layer 40 and the optional conductive metal sulfide-oxide compound layer 46 of the present disclosure can provide lower contact resistance for the n-type semiconductor portion of the photovoltaic p-n junction structure. The gradient in the metal-to-sulfide atomic ratio in the n-type compound semiconductor material layer 40 can optimize the performance of the p-n junction while simultaneously reducing the contact resistance for the n-type semiconductor portion of the photovoltaic p-n junction structure. Because manufacture of the photovoltaic cells 10 of the present disclosure can be performed on a web substrate employing a continuous processing sequence, the manufacturing process of the present disclosure can fabricate the photovoltaic cells 10 with a high throughput.

While sputtering was described as the preferred method for depositing all layers onto the substrate, some layers may be deposited by MBE, CVD, evaporation, plating, etc. It is to be understood that the present invention is not limited to the embodiment(s) and the example(s) described above and illustrated herein, but encompasses any and all variations falling within the scope of the appended claims. For example, as is apparent from the claims and specification, not all method steps need be performed in the exact order illustrated or claimed, but rather in any order that allows the proper formation of the photovoltaic cells of the embodiments of the present disclosure.

What is claimed is:

1. A method of making a photovoltaic device, comprising:
forming a p-type compound semiconductor material layer comprising copper, indium, gallium and a chalcogen over a substrate; and
forming an n-type metal sulfide layer on the p-type compound semiconductor material layer by sputtering process employing at least one metal and sulfur containing sputtering target having a non-stoichiometric composition in which a metal-to-sulfur atomic ratio is greater than 1.

2. The method of claim 1, wherein:
the p-type compound semiconductor material layer is formed in a first process module by a first sputtering process employing at least one first sputtering target comprising copper, indium, and gallium;
the n-type metal sulfide layer is formed in a second process module by a second sputtering process; and
the at least one metal and sulfur containing sputtering target comprises a second metal sulfide sputtering target having a metal-to-sulfur atomic ratio in a range from 1.05 to 1.20.

3. The method of claim 2, wherein:
the at least one metal and sulfur containing sputtering target comprises a plurality of second sputtering targets having different metal-to-sulfur atomic ratios; and
the n-type metal sulfide layer is formed with a gradient in a metal-to-sulfur atomic ratio therein along a direction perpendicular to a top surface of the n-type metal sulfide layer.

4. The method of claim 3, wherein:
the second process module comprises another second sputtering target having a metal-to-sulfur atomic ratio in a range from 0.95 to 1.03;
the second sputtering process deposits a first sublayer of the n-type metal sulfide layer by sputtering the another second sputtering target before depositing a second sublayer of the n-type metal sulfide layer by having the metal-to-sulfur atomic ratio in a range from 1.05 to 1.20; and
a metal-to-sulfur atomic ratio in the n-type metal sulfide layer increases with distance from the p-type compound semiconductor material layer.

5. The method of claim 2, wherein:
the p-type compound semiconductor material layer is formed as a polycrystalline material layer; and
the n-type metal sulfide layer is formed with epitaxial alignment with the p-type compound semiconductor material layer so that a predominant portion of grain boundaries of the n-type metal sulfide layer coincide with grain boundaries of the p-type compound semiconductor material layer at an interface between the n-type metal sulfide layer and the p-type compound semiconductor material layer.

6. The method of claim 5, further comprising flowing an oxidizer gas and a hydrogen-containing gas into the second processing chamber during the second sputtering process, whereby epitaxial alignment between the n-type metal sulfide layer and the p-type compound semiconductor material layer is induced during deposition of the n-type metal sulfide layer.

7. The method of claim 6, wherein:
a partial pressure of the oxidizer gas is maintained in a range from 0.025 mTorr to 1.0 mTorr in the second processing chamber during the second sputtering process; and
a partial pressure of the hydrogen-containing gas is maintained in a range from 0.05 mTorr to 2.0 mTorr and is greater than the partial pressure of the oxidizer gas in the second processing chamber during the second sputtering process.

8. The method of claim 2, further comprising depositing a conductive metal sulfide-oxide compound layer on the n-type metal sulfide layer in a third process module by a third sputtering process employing a third sputtering target and an oxidizing ambient.

9. The method of claim 8, wherein:
the conductive metal sulfide-oxide compound layer comprises zinc oxysulfide material in which 20 to 80 atomic percent of sulfur is substituted by oxygen; and
the n-type metal sulfide layer comprises a material selected from cadmium sulfide, zinc sulfide, and cadmium zinc sulfide.

10. The method of claim 1, further comprising forming a first electrode over the substrate prior to forming the p-type compound semiconductor material layer, and forming a second electrode over the n-type metal sulfide layer, wherein the n-type metal sulfide layer comprises cadmium sulfide having a metal-to-sulfur atomic ratio greater than 1.

11. A semiconductor device manufacturing apparatus, comprising:
a first process module configured to receive a substrate through a first entrance and to extract the substrate through a first exit and including at least one first sputtering target comprising copper, indium, and gallium and a chalcogen source and configured for deposition of a p-type compound semiconductor material layer comprising copper, indium, gallium and a chalcogen over the substrate during transit therethrough; and
a second process module configured to receive the substrate from the first process module through a second entrance and to extract the substrate through a second exit and including at least one second sputtering target configured for deposition of an n-type metal sulfide layer on the substrate during transit of the substrate through the second process module, wherein one of the at least one second sputtering target comprises a second sputtering target having a non-stoichiometric composition in which a metal-to-sulfur atomic ratio is greater than 1.

12. The semiconductor device manufacturing apparatus of claim 11, wherein:
the at least one second sputtering target comprises a plurality of second sputtering targets having different metal-to-sulfur atomic ratios; and
the second process module is configured to deposit the n-type metal sulfide layer with a gradient in a metal-to-sulfur atomic ratio therein along a direction perpendicular to a top surface of the n-type metal sulfide layer.

13. The semiconductor device manufacturing apparatus of claim 12, wherein:
the second sputtering target having the non-stoichiometric composition in which the metal-to-sulfur atomic ratio is greater than 1 comprises the second sputtering target having the metal-to-sulfur atomic ratio in a range from 1.05 to 1.20;
the plurality of second sputtering targets comprises another second sputtering target having a metal-to-sulfur atomic ratio in a range from 0.95 to 1.03; and
the second process module is configured to deposit a first sublayer of the n-type metal sulfide layer by sputtering the another second sputtering target before depositing a second sublayer of the n-type metal sulfide layer by sputtering the second sputtering target having the metal-to-sulfur atomic ratio in a range from 1.05 to 1.20.

14. The semiconductor device manufacturing apparatus of claim 12, wherein the second process module is configured to deposit the n-type metal sulfide layer such that a metal-to-sulfur atomic ratio in the n-type metal sulfide layer increases with distance from the p-type compound semiconductor material layer.

15. The semiconductor device manufacturing apparatus of claim 11, further comprising:
an oxidizer gas supply system connected to the second process module and configured to flow an oxidizer gas into the second process module during deposition by the second sputtering process; and
a hydrogen-containing gas supply system connected to the second process module and configured to flow a hydrogen-containing gas into the second processing chamber during the second sputtering process.

16. The semiconductor device manufacturing apparatus of claim 15, wherein the hydrogen-containing gas supply system and the oxidizer gas supply system are configured to maintain a partial pressure of the hydrogen-containing gas higher than a partial pressure of the oxidizer gas.

17. The semiconductor device manufacturing apparatus of claim 11, further comprising a third process module configured to receive the substrate from the second process module through a third entrance and to extract the substrate through a third exit and including a third sputtering target containing a metal sulfide material and an oxidizer gas supply system that are configured for deposition of a conductive metal sulfide-oxide compound layer over the substrate during transit of the substrate through the third process module.

18. The semiconductor device manufacturing apparatus of claim 11, wherein each of the at least one second sputtering target comprises a material selected from cadmium sulfide, zinc sulfide, and cadmium zinc sulfide.

19. A method of making a semiconductor device, comprising:
forming a p-type compound semiconductor material layer comprising copper, indium, gallium, and a chalcogen over a substrate in a first process module by a first sputtering process employing at least one first sputtering target comprising copper, indium, and gallium;
forming an n-type metal sulfide layer on the p-type compound semiconductor material layer in a second process module by a second sputtering process employing at least one second sputtering target; and
forming a conductive metal sulfide-oxide compound layer on the n-type metal sulfide layer in a third process module by a third sputtering process employing a third sputtering target in an oxidizing ambient.

20. The method of claim 19, wherein;
the n-type metal sulfide layer comprises metal rich cadmium sulfide;
the at least one second sputtering target has a non-stoichiometric composition in which a metal-to-sulfur atomic ratio is in a range from 1.05 to 1.20; and
the conductive metal sulfide-oxide compound layer comprises zinc oxysulfide.

21. A photovoltaic cell, comprising:
a first electrode located over a substrate;
a p-type compound semiconductor material layer located over the first electrode layer and comprising copper, indium, gallium and a chalcogen;
a polycrystalline metal rich metal sulfide n-type compound semiconductor material layer located over the p-type compound semiconductor material layer; and
a second electrode located over the metal rich metal sulfide n-type compound semiconductor material layer.

22. The photovoltaic cell of claim 21, wherein:
the polycrystalline metal rich n-type metal sulfide layer has an epitaxial alignment with the p-type compound semiconductor material layer so that a predominant portion of grain boundaries of the polycrystalline metal rich n-type n-type metal sulfide layer coincide with grain boundaries of the p-type compound semiconductor material layer at an interface between the polycrystalline metal rich n-type metal sulfide layer and the p-type compound semiconductor material layer;

23. The photovoltaic cell of claim 21, further comprising a conductive metal sulfide-oxide compound layer located over the metal rich metal sulfide n-type compound semiconductor material layer.

24. The photovoltaic cell of claim 23, wherein:
the conductive metal sulfide-oxide compound layer comprises zinc oxysulfide;
the p-type compound semiconductor material layer comprises a CIGS layer; and
the metal rich metal sulfide n-type compound semiconductor material layer is selected from cadmium sulfide, zinc cadmium sulfide and zinc cadmium sulfide having a metal-to-sulfur atomic ratio is in a range from 1.05 to 1.20.

25. A photovoltaic cell, comprising:
a first electrode located over a substrate;
a p-type compound semiconductor material layer located over the first electrode layer and comprising copper, indium, gallium and a chalcogen;
a metal sulfide n-type compound semiconductor material layer located over the p-type compound semiconductor material layer;
a conductive metal sulfide-oxide compound layer located over the metal sulfide n-type compound semiconductor material layer; and
a second electrode located over the conductive metal sulfide-oxide compound layer.

26. The photovoltaic cell of claim 25, wherein:
the conductive metal sulfide-oxide compound layer comprises zinc oxysulfide;
the p-type compound semiconductor material layer comprises a CIGS layer; and
the metal sulfide n-type compound semiconductor material layer comprises cadmium sulfide.
